(19) United States
(12) Patent Application Publication
(10) Pub. No.: US 2007/0069260 A1
(43) Pub. Date: Mar. 29, 2007

(54) Photodetector structure for improved collection efficiency

(75) Inventor: Eric G. Stevens, Webster, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/489,902

(22) Filed: Jul. 20, 2006

Related U.S. Application Data
(60) Provisional application No. 60/721,175, filed on Sep. 28, 2005.

(51) Int. Cl. H01L 31/113

(52) U.S. Cl. 257/292

(57) ABSTRACT

An image sensor with an image area having a plurality of photodetectors of a first conductivity type includes a substrate of the second conductivity type; a first layer of the first conductivity type substantially spanning an area of each photodetector; wherein the first layer abuts each photodetector and is between the substrate and each photodetector.

### CROSS-REFERENCE TO RELATED APPLICATIONS

This is a 111A application of Provisional Application Ser. No. 60/721,175, filed Sep. 28, 2005.

### FIELD OF THE INVENTION

The invention relates generally to the field of image sensors, and more particularly, to such image sensors having a lightly doped layer of the same conductivity type as the collection region of photo-detectors for reducing cross talk.

### BACKGROUND OF THE INVENTION

As is well known in the art, active CMOS image sensors typically consist of an array of pixels. Typically, each pixel consists of a photodetector element and one or more transistors to read out a voltage representing the light sensed in the photodetector. FIG. 1 a shows a typical pixel layout for an active pixel image sensor. The pixel consists of a photodiode photodetector (PD), a transfer gate (TG) for reading out the photogenerated charge onto a floating diffusion (FD), which converts the charge to a voltage. A reset gate (RG) is used to reset the floating diffusion to voltage VDD prior to signal readout from the photodiode. The gate (SF) of a source follower transistor is connected to the floating diffusion for buffering the signal voltage from the floating diffusion. This buffered voltage is connected to a column buss (not shown) at V_{OUT} through a row select transistor gate (RS), used to select the row of pixels to be read out.

As the demand for higher and higher resolution within a given optical format pushes pixel sizes smaller and smaller, it becomes increasingly more difficult to maintain other key performance aspects of the device. In particular, quantum efficiency and cross talk of the pixel start to severely degrade as pixel size is reduced. (Quantum efficiency drops and cross talk between pixels increases). Cross talk is defined as the ratio of the signal in the non-illuminated to the illuminated pixel(s), and can be expressed as either a fraction or percentage. Therefore, cross talk represents the relative amount of signal that does not get collected by the pixel(s) under which it was generated. Recently, methods have been described to improve quantum efficiency, but at the expense of increased cross talk. (See FIG. 4 in U.S. Pat. No. 6,225,670). Alternatively, vertical-overflow drain (VOD) structures used for blooming protection have been employed which reduce cross talk (S. Inoue et al., “A 3.25 M-pixel APS-C size CMOS Image Sensor,” in Eisoseiho Media Gakkai Gijutsu Hokoku (Technology Report, Image Information Media Association) Eiseigakugiko, vol. 25, no. 28, pp.37-41, March 2001. ISSN 1342-6893.) at the expense of quantum efficiency.

Increasing the depletion depth of the photodetector will increase the collection efficiency of the device, thereby improving both quantum efficiency and cross talk properties. In the past, this has been achieved by reducing the doping concentration of the bulk material in which the detector is made. However, this approach is known to result in reduced charge capacity (for a given empty-diode potential) and increased dark-current generation (from the increase in the bulk diffusion component) thereby reducing the dynamic range and exposure latitude of the detector. Additionally, the lower the doping level, the more difficult it is to control.

U.S. Pat. 6,297,070 discloses a deep photodiode but does not disclose the addition of a lightly doped layer between the photodetector and the substrate, as in the present invention, for increasing the collection depth even further along with the other advantages described herein.

Still further, in the prior art, the n-type region of a pinned photodiode was formed using a single, relatively shallow implant as illustrated by way of example in FIGS. 1b and 1c. The resulting potential profile for such a prior-art empty photodiode is shown in FIG. 1d. From this figure, it can be seen that the depletion depth (the point at where the gradient of the electric potential goes to zero) for this example prior-art pixel structure is only about 1.2 um. At green and red wavelengths the absorption depth in silicon is greater than this depletion depth. Therefore, any carriers generated greater than this depletion depth can diffuse laterally into adjacent photosites which contributes to cross talk.

Therefore, there exists a need within the art to provide a structure that improves both quantum efficiency and cross talk attributes simultaneously, without reducing charge capacity or other imaging performance characteristics.

### SUMMARY OF THE INVENTION

The present invention is directed to overcoming one or more of the problems set forth above. Briefly summarized, according to one aspect of the present invention, the invention resides in an image sensor with an image area having a plurality of photo-detectors of a first conductivity type comprising a substrate of the second conductivity type; a first layer of the first conductivity type substantially spanning an area of each photodetector; wherein the first layer abuts each photodetector and is between the substrate and each photo-detector.

Advantageous Effect Of The Invention

The present invention has the following advantages of improving both quantum efficiency and cross talk attributes simultaneously, without reducing charge capacity or other imaging performance characteristics.

### BRIEF DESCRIPTION OF THE DRAWINGS

FIG. 1a is a top view of a prior art pixel;

FIG. 1b is a cross section of FIG. 1a through the photodiode, transfer gate and floating diffusion;

FIG. 1c is a doping profile through the center of the photodiode of FIG. 1a;

FIG. 1d is the potential profile through the center of the photodiode of FIG. 1a;

FIG. 2 is a two dimensional calculation of the internal quantum efficiency and cross talk vs. photodiode depletion depth for the present invention;

FIG. 3a is top view of an image sensor of the present invention;

FIG. 3b is a cross section of FIG. 3a through the photodiode, transfer gate and floating diffusion;

FIG. 3c is a doping profile through the center of the photodiode of FIG. 3a;

FIG. 3d is the potential profile through the center of the photodiode of FIG. 3a;

FIG. 4 is an illustration of a digital camera of the present invention having the image sensor of the present invention therein; and

FIG. 5 is a top view of the image senor of the present invention illustrating an array of pixels.

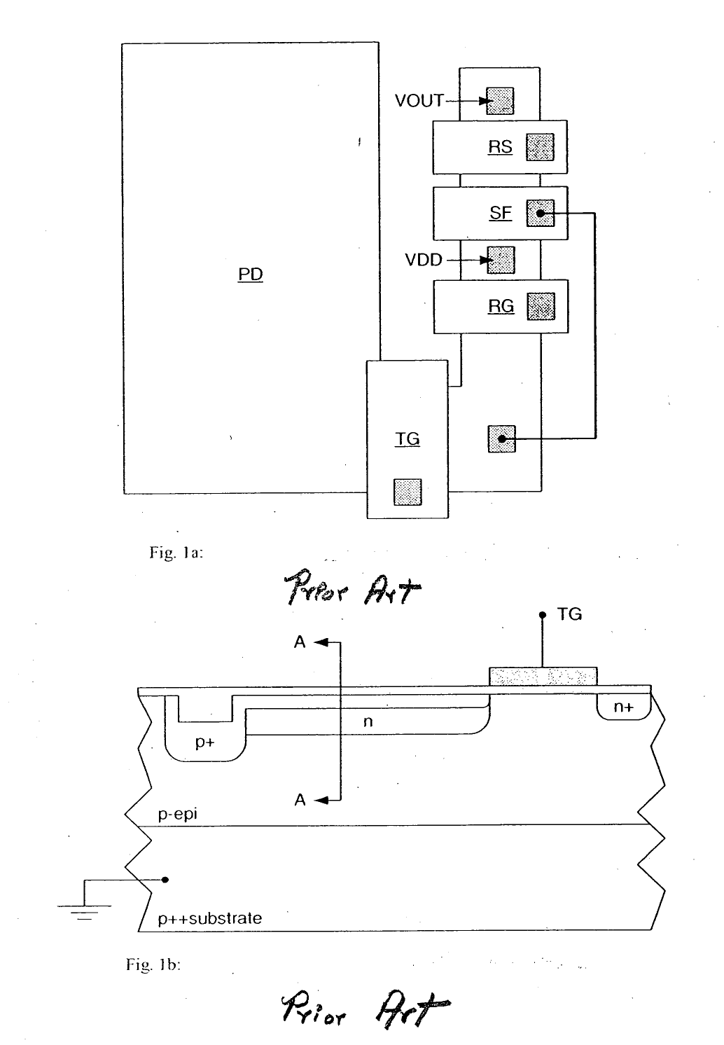

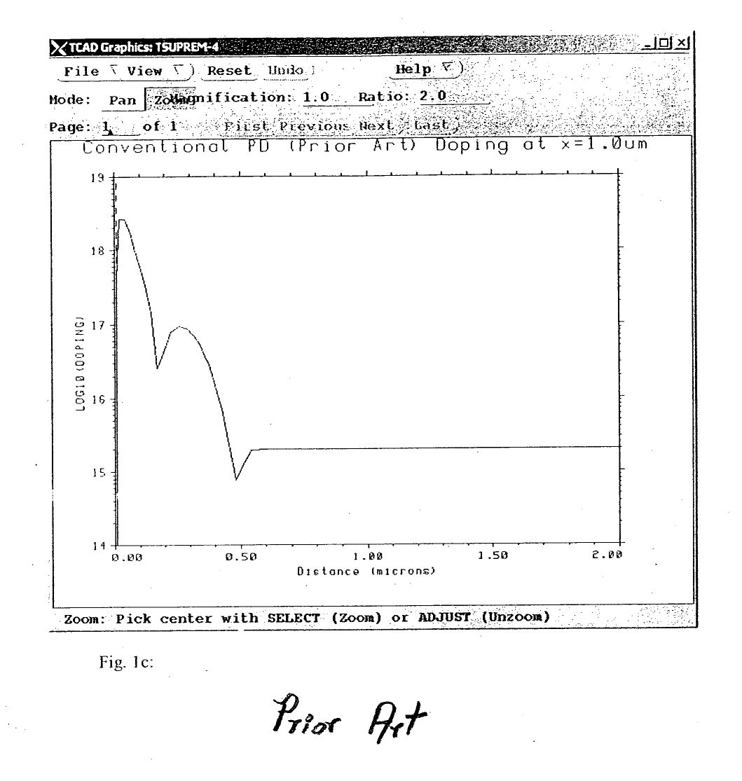

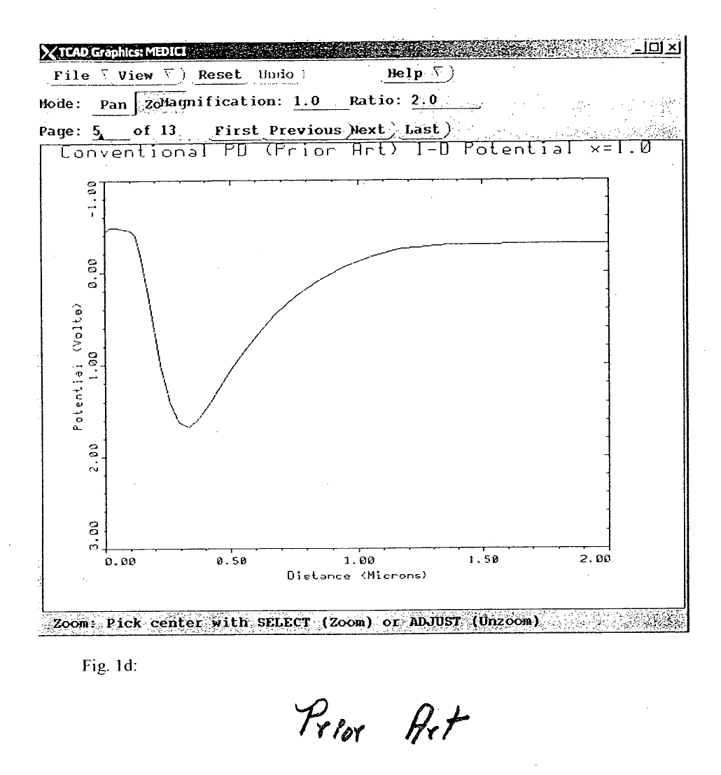

### DETAILED DESCRIPTION OF THE INVENTION

Before discussing the present invention in detail, it is instructive to note that the present invention is preferably used in, but not limited to, a CMOS active pixel sensor. Active pixel sensor refers to active electrical elements, particularly transistors, within the pixel such as the amplifier, reset transistor and row select transistor, but not to passive transistors functioning as a switch such as a tranfer gate and its associated source and drain. CMOS refers to complementary metal oxide silicon type electrical components having transistors, which are associated with the pixel, but typically not in the pixel, of one dopant type and transistors either passive or active within the pixel having sources and drains of the opposite dopant type. CMOS devices typically consume less power. Alternatively, CMOS may also have the transistors of opposite dopant type both within the pixel.

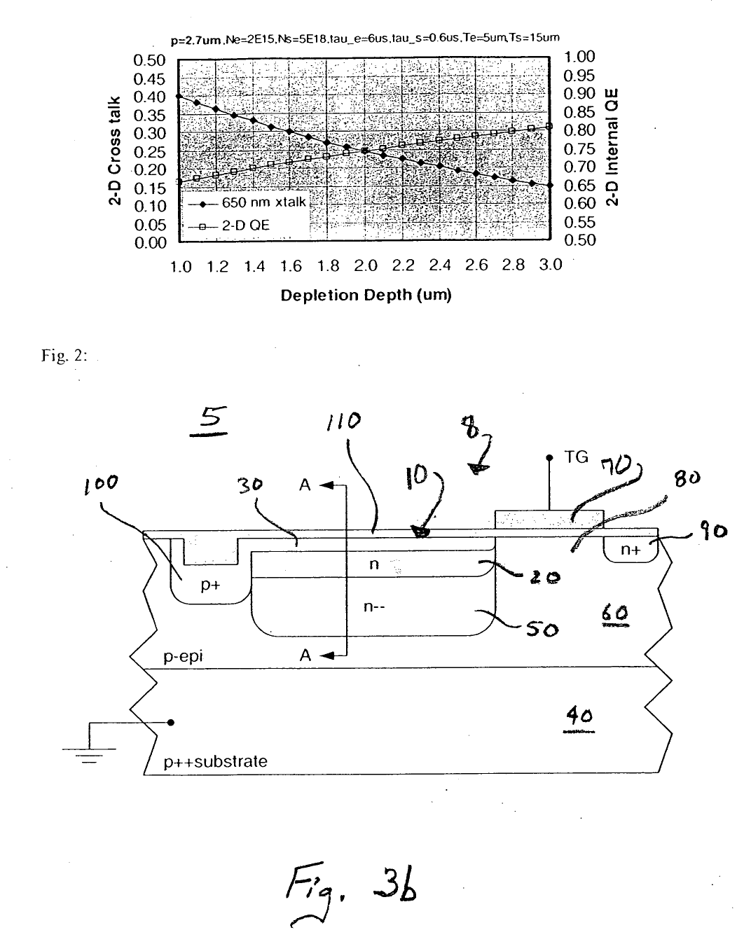

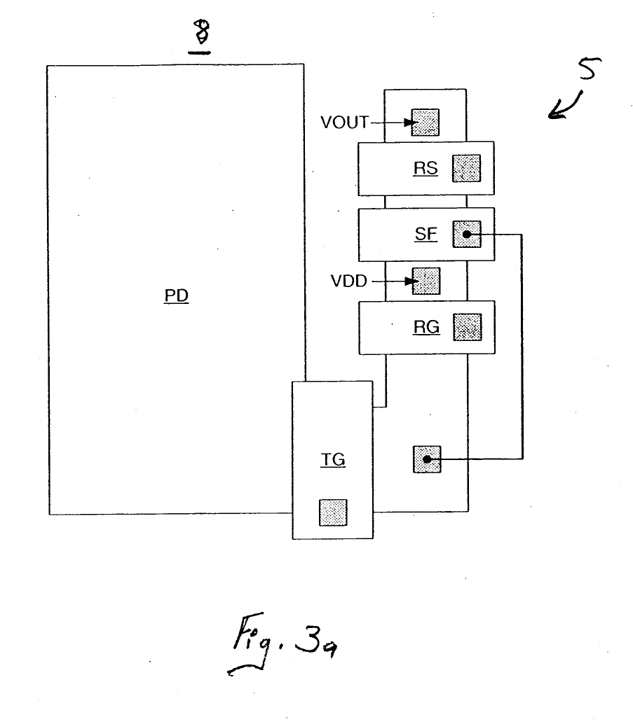

Before discussing the present invention in detail, it is beneficial to understand cross talk in image sensors. In this regard, cross talk is defined as the ratio of the signal in the non-illuminated to the illuminated pixel(s), and can be expressed as either a fraction or percentage. Therefore, cross talk represents the relative amount of signal that does not get collected by the pixel(s) under which it was generated. The dependence of cross talk and internal quantum efficiency (no reflection or absorption losses from any layers covering the photodetector) on depletion depth for an example pixel is illustrated in FIG. 2. The cross talk calculation assumes that every other pixel along a line is illuminated (and the alternating, interleaved pixels are not.) A wavelength of 650 nm was assumed, since cross talk is more of a problem at longer wavelengths. It can be seen from this figure that increasing the depletion depth can significantly reduce cross talk while increasing quantum efficiency. Still further, the photodetector's depletion depth as used herein is defined as the point furthest away from the surface at which the gradient of the electric potential goes to zero.

Therefore, from FIG. 2 it can be seen that the cross talk would be ˜36% and the internal quantum efficiency would be ˜68% for the prior-art structure. It can also be seen from FIG. 2 that cross talk can be significantly reduced by increasing the depletion depth.

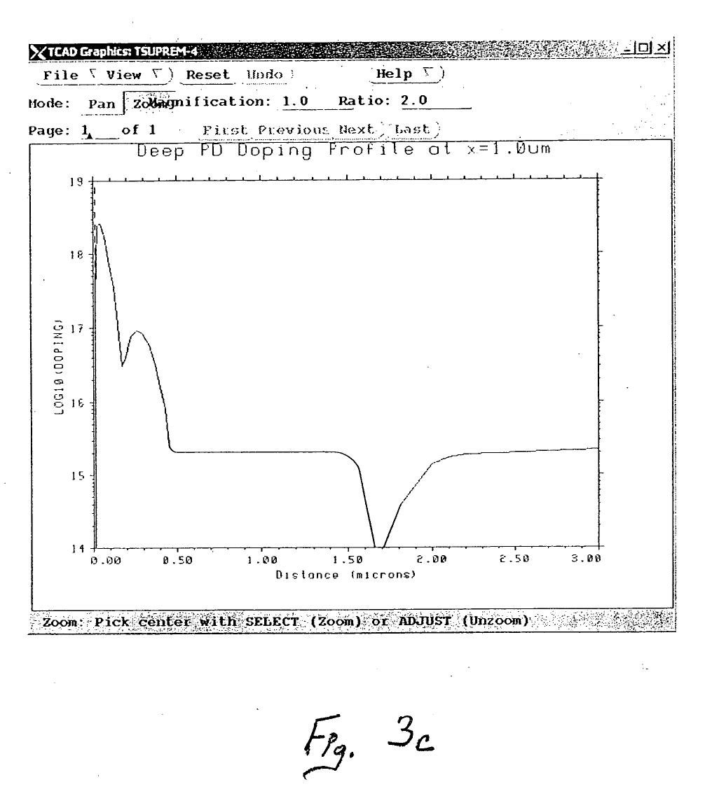

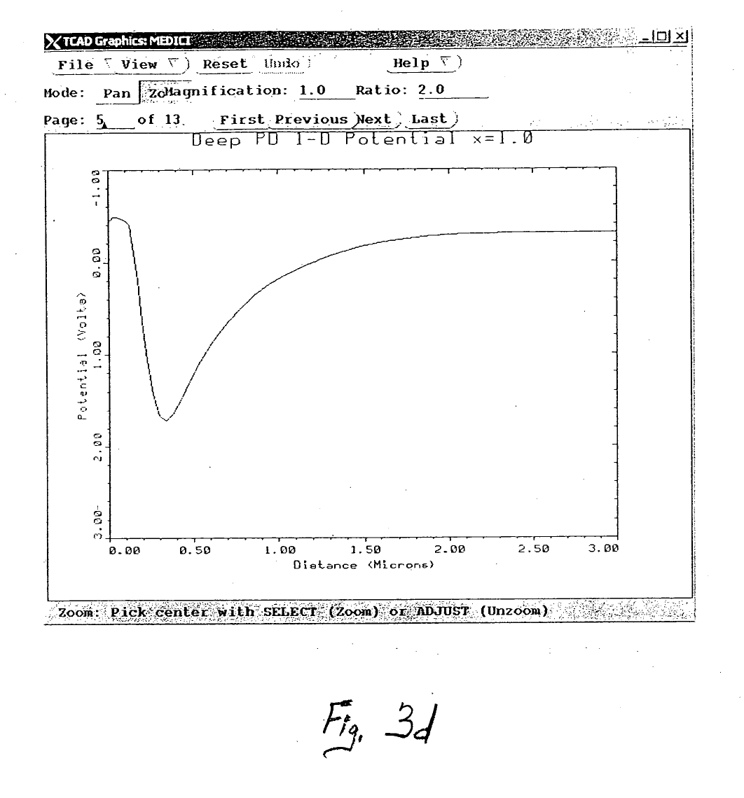

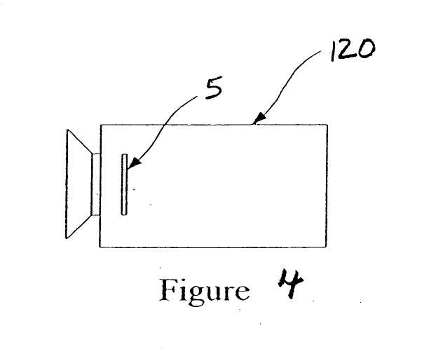

The present invention describes a photodetector structure for an active CMOS image sensor with an extended depletion depth to increase quantum efficiency and reduce pixel-to-pixel cross talk while maintaining good charge capacity and dynamic range characteristics. The top view of a CMOS image sensor pixel of the present invention incorporating this photodetector structure is shown in FIG. 3a. The CMOS image sensor of the present invention includes of an array of pixels. The pixel consists of a photodiode photodetector (PD), a transfer gate (TG) for reading out the photogenerated charge onto a floating diffusion (FD), which converts the charge to a voltage. A reset gate (RG) is used to reset the floating diffusion to voltage VDD prior to signal readout from the photodiode. The gate (SF) of a source follower transistor is connected to the floating diffusion for buffering the signal voltage from the floating diffusion. This buffered voltage is connected to a column buss (not shown) at V_{OUT} through a row select transistor gate (RS), used to select the row of pixels to be read out.

Although the preferred embodiment shown includes a pinned photodiode consisting of a p+pinning (top surface) layer and an n-type buried collecting region within a p-epi/p++substrate, it will be understood that those skilled in the art that other structures and doping types can be used without departing from the scope of the invention. For example, a simple unpinned n-type diode formed in a p-type substrate, or a p-type diode formed in an n-type substrate could be used, if desired. Another alternative embodiment would be to have the photodetector residing in a p-type well within an n-type substrate, as would be well known by those skilled in the art. It is also noted that only a portion of the image sensor of the present invention is shown for clarity. For example, although only one photo-detector is shown, there are a plurality of photo-detectors arranged in either a one or two-dimensional array.

Referring briefly to FIG. 5, there is shown the image sensor 5 of the present invention having a plurality of pixels 8 arranged in either a one-dimensional or two-dimensional array.

Referring to FIG. 3b, there is shown a side view in cross section of an image sensor 5 of the present invention. The image sensor 5 includes an imaging portion having a plurality of photo-detectors 10, preferably pinned photodiodes of two conductivity types, preferably n-type collection region 20 and p-type pinning layer 30. A substrate 40 of a conductivity type, preferably p type for the preferred embodiment, forms a base portion for the image sensor. A first layer 50 of a conductivity type, preferably n type, spans the photodiode area. It is noted that the first layer 50 physically contacts the n collection region 20 of the photodiode 10 thereby extending the depletion region and photo collection region of the photodiode 10. Optionally, a second layer 60, preferably a p-epitaxial layer, may be positioned between the first layer 50 and the substrate 40.

The first layer 50 and its associated depletion region effectively increase the collection volume of the photodiode 10. The first layer 50 and its associated depletion region will direct all or substantially all of the electrons generated within it, back into the photodiode 10 to which this particular first layer 50 is connected. Therefore, these electrons are no longer free to diffuse laterally to adjacent photosites where they might otherwise have been captured resulting in cross talk.

For thoroughness, it is noted that the pixel 8 of the image sensor 5 includes a transfer gate 70 for electrically controlling a channel 80 within the silicon for passing charge from the photodiode 10 through the channel to a floating diffusion 90 of a conductivity type (preferably n type), which converts the charge to a voltage. A channel stop 100 of a conductivity type, preferably p type, is adjacent the photodiode 10. A top layer 110 forms a dielectric as is well know in the art.

Therefore, the present invention extends the depletion depth, thereby reducing cross talk without reducing QE. The present invention adds a deep and relatively low concentration layer (first layer), which contacts the back of the main, higher concentration surface portion of the doping profile within the photodetector as illustrated by the example structure as shown in FIG. 3b and 3c. This deep, low-concentration layer (first layer) can be formed via a series, or chain of relatively low-dose, multiple high-energy implants and/or thermal drive.

FIG. 3d shows the resulting potential profile down into the base of the detector, from which it can be seen that the depletion depth of this example of the new structure is around 2.3 um. This depletion depth could be extended even further by increasing the depth of the metallurgical junction, which is a function of implant energy and/or thermal drive time of the preferred embodiment.

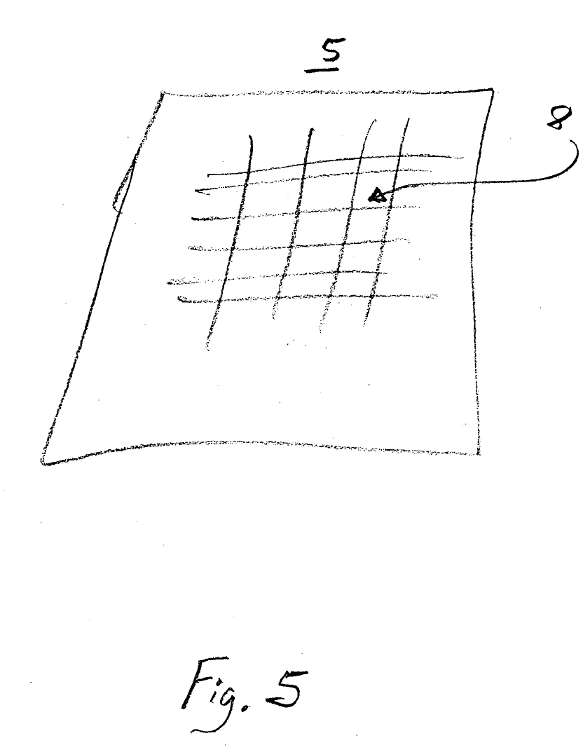

Referring to FIG. 4, a digital camera 120 having the image sensor 5 of the present invention disposed therein is shown for illustrating a typical commercial embodiment for the present invention.

The invention has been described with reference to a preferred embodiment. However, it will be appreciated that variations and modifications can be effected by a person of ordinary skill in the art without departing from the scope of the invention.

### PARTS LIST

5 image sensor
8 pixel
10 photodiode
20 n collection region
30 pinning layer
40 substrate
50 first layer
60 epitaxial layer
70 transfer gate
80 transfer channel
90 floating diffusion
100 channel stop
110 dielectric layer
120 digital camera

1. An image sensor with an image area having a plurality of photo-detectors of a first conductivity type comprising:
(a) a substrate of the second conductivity type;
(b) a first layer of the first conductivity type substantially spanning an area of each photodetector;
wherein the first layer abuts each photodetector and is between the substrate and each photo-detector.

2. The image sensor as in claim 1, wherein the first layer substantially spans a portion or all of the area of each photodetector.

3. The image sensor as in claim 2 wherein the photo-detector is a pinned photodiode of both the first and second conductivity type.

4. The image sensor as in claim 2, wherein the first conductivity type is n type and the second conductivity type is p type.

5. The image sensor as in claim 2, wherein the first layer is of the first conductivity type is of lighter doping concentration than the concentration of the photo-detector.

6. The image sensor as in claim 2 further comprising an epitaxial layer of second conductivity type between the substrate and the first layer.

7. A digital camera comprising:
an image sensor with an image area having a plurality of photo-detectors of a first conductivity type comprising:
(a) a substrate of the second conductivity type;
(b) a first layer of the first conductivity type substantially spanning an area of each photodetector;
wherein the first layer abuts each photodetector and is between the substrate and each photo-detector.

8. The camera as in claim 7, wherein the first layer substantially spans a portion or all of the area of each photodetector.

9. The digital camera as in claim 8 wherein the photo-detector is a pinned photodiode of both the first and second conductivity type.

10. The digital camera as in claim 8, wherein the first conductivity type is n type and the second conductivity type is p type.

11. The digital camera as in claim 8, wherein the first layer is of the first conductivity type is of lighter doping concentration than the concentration of the photo-detector.

12. The digital camera as in claim 8 further comprising an epitaxial layer of second conductivity type between the substrate and the first layer.
